(19) United States
(12) Patent Application Publication
(10) Pub. No.: US 2004/0107897 A1
(43) Pub. Date: Jun. 10, 2004

(54) Atomic layer deposition apparatus and method for preventing generation of solids in exhaust path

(76) Inventors: Seung-Hwan Lee, Seoul (KR); Kang-Soo Chu, Suwon-city (KR); Joo-Won Lee, Suwon-city (KR); Jae-Eun Park, Yongin-city (KR); Jong-Ho Yang, Seoul (KR)

Correspondence Address: HARNESS, DICKEY & PIERCE, P.L.C., P.O. BOX 8910, RESTON, VA, 20195, US

(21) Appl. No.: 10/640,244

(22) Filed: Aug. 14, 2003

(30) Foreign Application Priority Data
Dec. 5, 2002 (KR) 2002-77034

(51) Int. Cl. C30B 1/00

(52) U.S. Cl. 117/200

(57) ABSTRACT

Provided is an atomic layer deposition (ALD) apparatus in which the generation of powders is suppressed by providing a largely dedicated exhaust path for each of the reactants utilized in the ALD process. The ALD apparatus includes a reactor in which an ALD process is performed on a wafer using two or more types of reactants; reactant suppliers, each of which alternately supplies a different reactant to the reactor; and an exhaust path for each type of reactant so that the non-reacted portion of the reactants removed from the reaction chamber do not mix and react in the exhaust path.

This application claims priority under 35 U.S.C. §119 from Korean Patent Application No. 2002-77034, filed on Dec. 5, 2002, in the Korean Intellectual Property Office, the disclosure of which is incorporated herein in its entirety by reference.

### BACKGROUND OF THE INVENTION

1. Field of the Invention

The present invention relates to apparatuses for manufacturing semiconductor devices, and more particularly, to an improved atomic layer deposition (ALD) apparatus that can reduce the generation of solids in exhaust paths resulting from the combination of non-reacted reactants removed from the main deposition chamber.

2. Description of the Related Art

As the scale of semiconductor devices has decreased, the need for ultra-thin layers has gradually increased. According to International Technology Roadmap for Semiconductors (ITRS), published in late 2001, formation of thin layers necessitates a lower thermal budget and the need for ultra-thin layers is increasing. Also, as the size of contact holes are decreased, problems associated with step coverage and loading effects tend to increase. Atomic layer deposition (ALD) methods have been proposed as a means for overcoming various problems resulting from the increased integration of semiconductor devices. In recent years, extensive studies have been conducted on ALD techniques and attempts to apply ALD techniques to mass production have been made for several unit processes.

The ALD technique enables a material layer to be grown to a desired thickness by repeatedly forming very thin (i.e., atomic) layers of a desired material using two types of reactants sequentially applied to a reaction chamber. ALD techniques obtain an AB material layer by reacting minute quantities of two reactants, AX(g) and BY(g), on the surface of a substrate. The thickness of the AB material layer is increased by repeating the sequential supply and reaction of the AX(g) and BY(g) reactants generating XY(g) as a by-product. The deposition reaction can be generally represented by Equation I.

AX(g)+BY(g)→AB(s)+XY(g) I

More specifically, in an ALD process, a first reactant, AX(g), is supplied to a reactor chamber which a semiconductor substrate, such as a wafer, is provided. The first reactant AX(g) may be referred to as a “precursor” and is a compound obtained by combining an element A that will be used to form the desired AB material layer with a chemical X. The first reactant AX(g), supplied to the reactor, may react with a surface of the substrate, or be chemically or physically adsorbed in the surface of the substrate. Here, since the absorption reaction can be regarded as the actual reaction, the first reactant layer of the chemically absorbed AX (or chemisorbed) is formed on the atomic-size level.

Next, the non-chemisorbed portion of first reactant AX(g) is removed from inside the reactor. This removal may be performed using vacuum exhausting or vacuum pumping. Alternatively, the vacuum exhaust process may comprise purging the reactor with an inert gas such as N₂ or Ar. The physically-absorbed AX as well as the non-absorbed first reactant AX(g) are removed from the surface of the substrate and then exhausted. As a result, only the chemisorbed or reacted AX layer remains on the substrate.

A second reactant BY(g) is then supplied to the reactor. The second reactant BY(g) is also referred to as a “precursor” and is a compound obtained by combining an element B necessary to form the desired AB material layer with a chemical Y. A portion of the second reactant BY(g) reacts with the chemisorbed layer of AX according to Equation I, thereby forming a thin “atomic” AB(s) layer on the substrate and generating the by-product XY(g). The non-reacted portion of the second reactant BY(g) and the reaction by-product XY(g) are then removed from the reactor, typically by vacuum exhausting and/or purging with an inert gas.

The resulting AB(s) layer is formed roughly on the atomic-size level. Accordingly, to form the AB material layer having the desired thickness, the cycle of supply, exhaustion, and purging of the AX(g) and BY(g) reactants is typically repeated several times.

As described above, the ALD process necessitates the step of exhausting the non-reacted reactants or precursors. The individual non-reacted reactants may not cause any problems themselves. However, when two types of non-reacted reactants are mixed, i.e., when AX(g) combines with BY(g), they may explosively react to produce the desired material, AB(s), in undesirable locations (other than the substrate surface). In other words, if the reaction of Equation I occurs at a position other than at the substrate surface, powders and particulates may be generated, contaminating the ALD apparatus. In particular, the non-reacted reactants removed from the reaction chamber may combine in an exhaust path, thus generating particulate contaminants in the exhaust path.

FIG. 1 is a schematic view illustrating an exhaust path of a conventional ALD apparatus. As illustrated in FIG. 1, the ALD apparatus comprises a reactor 10, in which the ALD process is performed, and a pump 20 for exhausting non-reacted reactant gases or by-products from the reactor 10 and scrubber 30 installed downstream of the pump 20.

As also illustrated in FIG. 1, first exhaust line 41 connects the reactor 10 and the pump 20, a second exhaust line 45 connects pump 20 and the scrubber 30, and a third exhaust line 49 connects the scrubber 30 to an exhaust duct (not shown). The first, second, and third exhaust lines 41, 45, and 49 constitute an exhaust path between the reactor 10 and the exhaust duct (not shown).

The ALD process comprises alternately supplying two or more different gaseous reactants to the reactor 10. Non-reacted reactants and/or reaction by-products are alternately exhausted through the exhaust path. If the two different non-reacted reactants happen to meet during the exhaust process, a reaction between the two different reactants may occur, generating solid by-products and may produce solid powders.

However, the conventional ALD apparatus of FIG. 1 includes only a single exhaust path and a single pump 20, which provides the driving force required to evacuate the reactor, the non-reacted reactants, can may allow unreacted AX(g) and BY(g) to meet in the exhaust path. In particular, the unreacted reactants may meet in the pump 20, the second exhaust line 45, the scrubber 30, or the third exhaust line 49.

The ALD process may further comprise a purge step or a vacuum exhausting step between the steps of supplying reactant. In the exhaust path beyond pump 20, however, the flow rate tends to be reduced and the exhaust speeds of the non-reacted reactants tend to be reduced, thus increasing the likelihood that the non-reacted reactants will meet. The conditions in the first exhaust line 41 feeding the pump 20 can be maintained at a relatively high flow rate and lower than atmospheric pressure. However, in the exhaust path behind the pump 20, the flow rate tends to be reduced and the pressure tends to increase and may approach atmospheric pressure. Accordingly, when the two different non-reacted reactants move from the pump 20 to the scrubber 30, they may be exposed to and meet under conditions of atmospheric pressure and ambient temperature.

If the non-reacted reactants, i.e., AX(g) and BY(g), meet under atmospheric pressure and ambient temperature, they may react explosively, generating AB(s) and XY(g). The AB(s) will tend to be deposited in the exhaust path as a result of the reduced flow rate, thus producing powders. As a result, the powders are generated mainly in the pump 20, the second exhaust line 45, and the scrubber 30.

The powder may flow backward into the reactor 10 due to a malfunction of the pump 20 or may act as the cause of pump-down of the pump 20. Also, large amounts of the powder accumulating in the exhaust path will tend to clog the exhaust path. In such an instance, the pump 20 will need to be disassembled and cleaned to remove the powders or, if irreparable, replaced with a new pump. In addition, the exhaust path plumbing will need to be replaced, or the powders periodically removed from the exhaust path. Since such repair and maintenance work tends to be costly and take much time, the generation of powders in the exhaust path increases the expense and reduces the throughput during the mass production of semiconductor devices. Methods for addressing this problem, such as cold trap, line purge, and line heating have been proposed, but have not proven effective for suppressing or preventing the generation of powders.

### SUMMARY OF THE INVENTION

The exemplary embodiment of the invention provides an ALD apparatus, in which remaining non-reacted reactants from an ALD process are exhausted from a reactor, without mixing in the exhaust path, thereby avoiding a reaction between the non-reacted reactants and the associated generation of by-products or powders.

In accordance with an exemplary embodiment of the invention, an ALD apparatus comprises: a reactor in which an atomic layer deposition (ALD) process is performed using two or more types of reactants; reactant suppliers, each of which alternately supplies the reactants to the reactor; and a plurality of exhaust paths equaling number of types of reactants. The exemplary embodiment of the invention provides that after the ALD process, each of the types of remaining non-reacted reactants is independently exhausted from the reactor through dedicated exhaust control valves, each of which selectively controls a respective exhaust path. This arrangement ensures that each of the types of non-reacted reactants is exhausted only through a predetermined exhaust path, thereby reducing the likelihood of any mixing in an exhaust path.

Here, each of the exhaust paths includes a pump which provides the driving force required for exhausting the non-reacted reactant, a scrubber installed at the rear end of the pump, and exhaust lines which connect the pump to the scrubber and connect the pump to the reactor. A pump and a scrubber are installed in each and every exhaust path and an exhaust control valve is installed in each of the exhaust paths between the pump and the reactor. The various exhaust paths may be combined into a single exhaust line at some point upstream of the exhaust control valves to provide a single exhaust line that is coupled to the reactor or they may be entirely separate. The exhaust control valves may be opened selectively when a predetermined reactant is supplied to the reactor and may be closed when the predetermined reactant is not being supplied to the reactor.

Another exemplary embodiment of the invention provides an ALD apparatus in which an atomic layer deposition (ALD) process is performed alternately using a first reactor and a second reactor, a first reactant supplier which supplies a first reactant to the first reactor, a second reactant supplier which supplies a second reactant to the second reactor, a supply line which connects the first reactant supplier and the second reactant supplier, a first supply control valve, installed at the supply line, for allowing the first reactant supplier to selectively supply the first reactant to the reactors, and a second supply control valve, installed at the supply line, for allowing the second reactant supplier to selectively supply the second reactant to the reactors. An exemplary ALD apparatus will also include a first pump which provides the driving force required for exhausting the remaining non-reacted first reactant from the reactors during the ALD process, a first scrubber installed at the rear end of the first pump, a first exhaust line that connects the first pump with the first scrubber and connects the first pump with the reactor, a second pump which provides the driving force required for exhausting the remaining non-reacted second reactant from the reactors during the ALD process, a second scrubber installed at the rear end of the second pump and a second exhaust line which connects the second pump with the second scrubber and connects the second pump with the reactor. An exemplary ALD apparatus will also include a first exhaust control valve, installed around the first exhaust line between the first pump and the reactors, for selectively opening the exhaust path such that the non-reacted first reactant is exhausted by the first pump, and a second exhaust control valve, installed around the second exhaust line between the second pump and the reactors, for selectively opening the exhaust path such that the non-reacted second reactant is exhausted by the second pump.

If a third reactant is used in the ALD process, the exemplary ALD apparatus may further comprise a third pump which provides the driving force required for exhausting the remaining non-reacted third reactant from the reactors during the ALD process, a third scrubber installed at the rear end of the third pump, a third exhaust line which connects the third pump with the third scrubber and connects the third pump with the reactor, and a third exhaust control valve, installed around the third exhaust line between the third pump and the reactor, for selectively opening the exhaust path such that the non-reacted third reactant is exhausted by the third pump.

Another exemplary embodiment of the invention, provides an ALD apparatus including two or more reactors in which an atomic layer deposition (ALD) process alternately using a first reactant and a second reactant is performed, a first reactant supplier which supplies the first reactant to each of the reactors, a second reactant supplier which supplies the second reactant to the reactors, a supply line which connects the first and second reactant suppliers with the reactors, first supply control valves, installed in the supply line, for allowing the first reactant supplier to selectively supply the first reactant to each of the reactors and second supply control valves, installed in the supply line, for allowing the second reactant supplier to selectively supply the second reactant to each of the reactors. An exemplary ALD apparatus will also include a first pump which provides the driving force required for exhausting the remaining non-reacted first reactor from the reactors during the ALD process, a first scrubber installed at the rear end of the first pump, a first exhaust line which connects the first pump with the first scrubber and connects the first pump with each of the reactors, a second pump which provides the driving force required for exhausting the remaining non-reacted second reactant from the reactors during the ALD process, a second scrubber installed at the rear end of the second pump and a second exhaust line which connects the second pump and the second scrubber and connects the second pump with each of the reactors. An exemplary ALD apparatus will also include first exhaust control valves, installed in the first exhaust line between the first pump and the reactors, for selectively configuring the exhaust path so that the non-reacted first reactant is exhausted by the first pump, and second exhaust control valves, installed in the second exhaust line between the second pump and the reactors, for selectively configuring the exhaust path so that the non-reacted second reactant is exhausted by the second pump.

The first exhaust line may branch upstream of the first pump and be coupled to each of the reactors, and the first exhaust control valves may be installed in the branching portions of the first exhaust line. Similarly, the second exhaust line may branch upstream of the second pump and be coupled to each of the reactors, and the second exhaust control valves may be installed in branching portions of the second exhaust line.

An exemplary ALD apparatus may be configured so that when the first reactant is selectively supplied to one of the reactors, the first exhaust control valve, which is installed in the branch of the first exhaust line coupled to the selected reactor, is opened and the second exhaust control valves are closed. Likewise, an exemplary ALD apparatus may be configured so that when the second reactant is selectively supplied to the selected reactor, the second exhaust control valve, which is installed at the branch of the second exhaust line coupled to the selected reactor, is opened and the first exhaust control valves are closed.

Alternatively, an exemplary ALD apparatus may be configured so that when the first supply control valves, which are installed in the supply line coupled to the reactors, are opened to supply the first reactant to one of the reactors, the first exhaust control valves, which are installed in branches of the first exhaust line coupled to the reactors, are opened and the second exhaust control valves are closed. Likewise, an exemplary ALD apparatus may be configured so that when the second supply control valves, which are installed in the supply line coupled to the reactors, are opened to supply the second reactant to the reactors, the second exhaust control valves, which are installed in branches of the second exhaust line coupled to the reactors, are opened and the first exhaust control valves are closed.

Alternatively, an exemplary ALD apparatus may be configured so that when the first reactant is selectively supplied to the reactors, the first exhaust control valves are opened, and the second exhaust control valves are closed, and that when the second reactant is selectively supplied to the reactors, the second exhaust control valves are opened, and the first exhaust control valves are closed.

Alternatively, an exemplary ALD apparatus may be configured so that when the first supply control valves are opened to supply the first reactant to the reactors, the second supply control valves are closed, the first exhaust control valves are opened, and the second exhaust control valves are closed. An exemplary ALD apparatus may be configured so that when the second supply control valves are opened to supply the second reactant to the reactors, the first supply control valves are closed, the second exhaust control valves are opened, and the first exhaust control valves are closed.

According to an exemplary embodiment of the invention, when a variety of reactants used in the ALD process are separately exhausted from the reactor, the different reactants can be effectively prevented from mixing and reacting with each other in the exhaust path, thus reducing or eliminating the generation of powders and/or solid deposits in the exhaust path.

### BRIEF DESCRIPTION OF THE DRAWINGS

The above and other features and advantages of the present invention will become more apparent by describing in detail preferred embodiments thereof with reference to the attached drawings in which:

FIG. 1 is a schematic diagram illustrating an exhaust path of a conventional ALD apparatus;

FIG. 2 is a schematic diagram illustrating an exhaust path of an ALD apparatus according to a first exemplary embodiment of the present invention;

FIG. 3 is a schematic diagram illustrating an exhaust path of an ALD apparatus according to a second exemplary embodiment of the present invention; and

FIGS. 4A and 4B are schematic diagrams illustrating first and second exhaust paths according to the exemplary embodiment of the apparatus illustrated in FIG. 2.

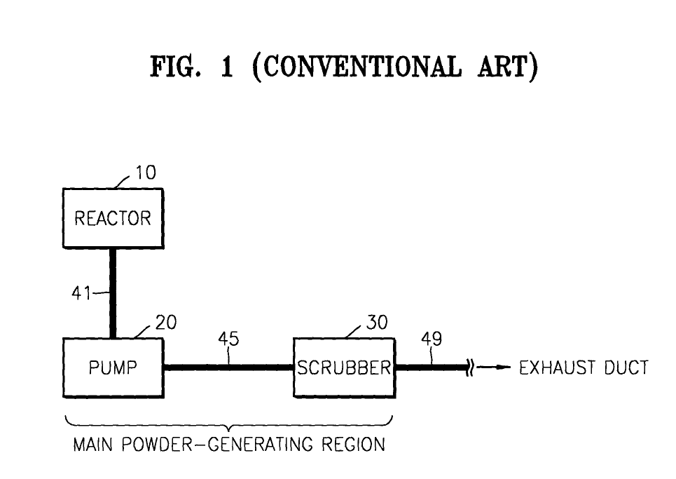

### DETAILED DESCRIPTION OF THE INVENTION

The present invention will now be described more fully with reference to the accompanying drawings, in which exemplary embodiments of the invention are shown. This invention may, however, be embodied in many different forms and should not be construed as being limited to the embodiments set forth herein. Rather, these embodiments are provided so that this disclosure is thorough and complete and fully conveys the concept of the invention to those skilled in the art. In the drawings, the size and configuration of the elements may be simplified or exaggerated for clarity, and the same reference numerals in different drawings represent the same element.

Exemplary embodiments of the present invention provide ALD apparatuses configured so that the non-reacted portion of each reactant is removed through a separate exhaust path, thereby reducing the likelihood that different reactants will meet in the exhaust path after having been removed from the reactor(s). This separation of the different types of non-reacted reactants reduces the likelihood of reactions in the exhaust path and reduces the formation of solid by-products and associated particulates and powders in the exhaust path.

### First Exemplary Embodiment

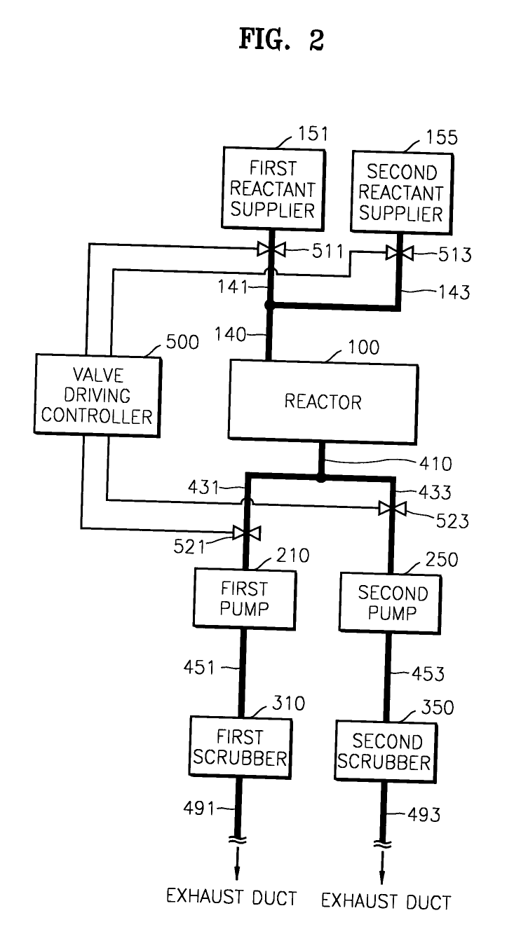

FIG. 2 is a schematic diagram illustrating an ALD apparatus according to a first exemplary embodiment of the invention. As illustrated in FIG. 2, the ALD apparatus according to the first exemplary embodiment of the invention comprises a reactor 100, reactant suppliers 151 and 155, pumps 210 and 250, and scrubbers 310 and 350.

For a single wafer type ALD apparatus, the reactor 100 may include a reaction or deposition chamber, which may include a wafer support, such as a chuck or wafer table, and a gas distributor, such as a shower head, for supplying reactant gases to the wafer surface. In a mini-batch ALD apparatus, the reactor 100 may include a reaction chamber configured to receive a small plurality of wafers, typically fewer than 7, for simultaneous processing.

For a batch type ALD apparatus, the reactor 100 may be structured to process a larger plurality of wafers. For example, the reactor 100 may include a vertical tube instead of a chamber and include a boat-type wafer support for supporting a plurality of wafers within in the tube. The tube may include a double tube design for distributing the reactant gas among the wafers arrayed within the reactor. As the batch-type ALD apparatus enables simultaneous processing of a plurality of wafers, it can increase process throughput and may be better suited for mass production than single wafer reactors.

As described above, the ALD process may be performed on one or more wafers that have been loaded into reactor 100. As described above, the ALD process comprises separately and alternately supplying two or more different reactants to a reactor 100 to form a desirable material layer on the atomic-size level by reacting the reactants on the wafer surface, and repeatedly performing the same steps to grow a material layer of sufficient thickness. Accordingly, the reactor 100 is connected to reactant suppliers 151 and 155 and supply lines 140, 141, and 143 for supplying two or more types of reactants to the reactor 100.

In a basic configuration, an exemplary apparatus includes a first reactant supplier 151 for supplying a first reactant, for example, AX(g), and a second reactant supplier 155 for supplying a second reactant, for example, BY(g), coupled to the reactor 100 through one or more supply lines. The apparatus may include, as illustrated in FIG. 2, a common supply lines 140 and dedicated supply lines 141, 143 as well as supply control valves 511, 513 for opening or closing the dedicated supply lines.

The reactants are preferably supplied in the gaseous phase to the reactor 100, for example, a chamber or a tube, during the performance of the ALD process. The reactants (or precursors) may, however, be in the liquid or solid phase under normal conditions. Thus, each of the reactant suppliers 151 and 155 may include equipment, such as vaporizer(s) and/or bubblers, for converting the reactants into gases that may be supplied to the reactor chamber.

Further, as illustrated in FIG. 2, each of the reactant suppliers 151, 155 may be coupled to the reactor 100 through first and second supply lines 141, 143. As illustrated, supply control valves 511, 513 may be installed in the supply lines 141, 143. For example, the first supply control valve 511 is installed in the first supply line 141, and the second supply control valve 513 is installed in the second supply line 143. These first and second supply control valves 511, 513 control the supply or flow of each of the reactants to the reactor as required for the ALD process being conducted. Thus, the first and second supply control valves 511, 513 allow the reactants to be supplied separately and sequentially to the reactor 100.

In addition to the supply lines 141, 143, the ALD apparatus may further include a nitrogen gas supply line (not shown) for supplying a nitrogen gas to the reactor 100. Here, the nitrogen gas is an example of a purging gas required for a purging process, which is introduced between supply periods of the respective reactants. Also, the nitrogen gas supply line may include a bypass path by using the supply lines 140, 141, and 143 for supplying the nitrogen to the reactor.

The first and second supply lines 141, 143 may be independently coupled to the reactor 100. Alternatively, as illustrated in FIG. 2, the first and second supply lines 141, 143 may be combined into an inlet line 140 that is, in turn, coupled to the reactor 100. In the single wafer type of reactor, the inlet line 140 may be coupled to a gas distributor such as a shower head, provided in the chamber of the reactor 100. Alternatively, when the reactor 100 includes a double tube reactor configuration, the inlet line 140 may be coupled to supply the reactants directly to an inner tube, into a space between an inner tube and an outer tube, or provide for other reactant entry points into the reactor.

When the inlet line 140 is used, as illustrated in FIG. 2, the first supply control valve 511 is installed in the first supply line 141, and the second supply control valve 513 is installed in the second supply line 143. Thus, each of the reactants can be separately supplied to the reactor 100 via the inlet line 140. Typically, when the first supply control valve 511 is opened to supply the first reactant, the second supply control valve 513 will be closed. Conversely, when the second supply control valve 513 is opened to supply the second reactant, the first supply control valve 511 will typically be closed.

The first reactant, for example AX(g), is supplied to the reactor 100 under conditions that will cause a portion of the reactant to be chemically absorbed (chemisorbed) or react on the surface of the wafer(s) present in the reactor 100 to form a surface layer. The non-reacted portion of the first reactant is then exhausted from the reactor 100. In the first exemplary embodiment of the present invention, the exhaust path is configured so that each of the non-reacted reactants is exhausted via a largely separate exhaust path.

As illustrated in FIG. 2, in order to exhaust the non-reacted reactants and the gaseous by-products from the reactor 100, the pumps 210 and 250 and scrubbers 310 and 350 are coupled to the reactor 100 by exhaust lines 410, 431, 433, 451, 453, 491 and 493. The total number of exhaust paths, each of which couples the reactor 100 to an exhaust duct, is preferably equal in number to the number of types of reactants that will be supplied to the reactor during the ALD process. For example, as shown in FIG. 2, when the ALD process utilizes two types of reactants, two independent exhaust paths are preferably connected to the reactor 100.

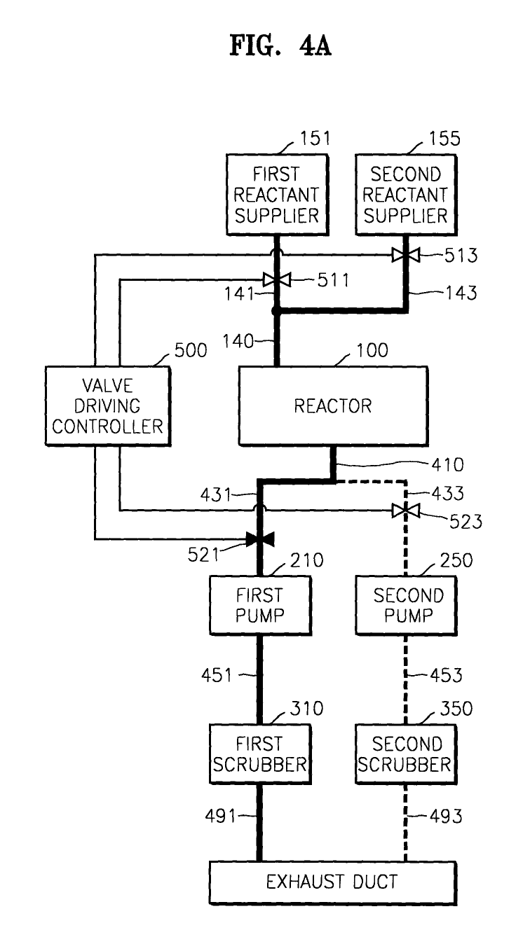

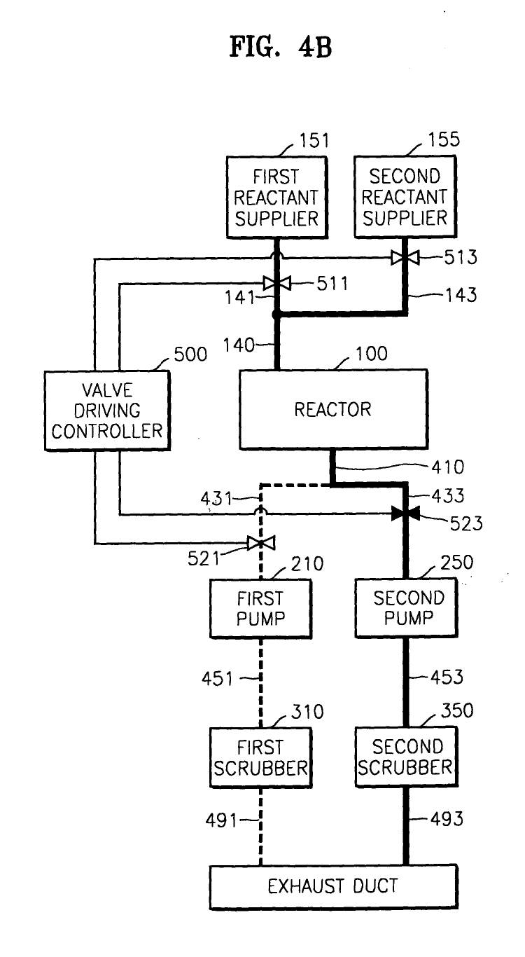

For example, as illustrated in FIG. 4A, a first exhaust path (heavy solid line) for exhausting the non-reacted first reactant may include the first exhaust line 431, the first pump 210, the second exhaust line 451, the first scrubber 310, and the third exhaust line 491, can be made active while a second exhaust path (dashed line) is inactive. Similarly, when a second exhaust path, as illustrated in FIG. 4B (heavy solid line), for exhausting the non-reacted second reactant may include the forth exhaust line 433, the second pump 250, the fifth exhaust line 453, the second scrubber 350, and the sixth exhaust line 493 while the first exhaust path (dashed line) is inactive.

Here, the first exhaust line 431 and the fourth exhaust line 433 may branch from a single outlet line 410 that is coupled to the reactor 100. The exhaust speed within outlet line 410 and exhaust lines 413 and 433 is typically relatively high as a result of the driving force provided by vacuum pumps 210 and 250, which may be diffusion and/or mechanical pumps. Accordingly, the likelihood that powders will be generated in the first and fourth exhaust lines 431 and 433 is reduced, even if the first and fourth exhaust lines 431 and 433 are coupled to the single outlet line 410 that is, in turn, coupled to the reactor 100.

During operation of the first exemplary embodiment of the invention, the non-reacted first reactant is exhausted through the first exhaust path and the non-reacted second reactant is exhausted through the second exhaust path. To achieve this sequence of operation, when material being exhausted from the reactor 100 includes the non-reacted first reactant, the first exhaust path is opened and the second exhaust path is closed as illustrated in FIG. 4A. Conversely, when material being exhausted from the reactor 100 includes the non-reacted second reactant, the second exhaust path is opened and the first exhaust path is closed as illustrated in FIG. 4B. Exhaust control valves 521 and 523 are utilized to control the alternate opening and closing of the first and second exhaust paths, such that the first and second exhaust paths are selectively opened and closed repeatedly in synchronization with the ALD process.

For instance, the first exhaust control valve 521 is installed in the first exhaust line 431, which is installed upstream of the first pump 210 in the first exhaust path, and the second exhaust control valve 523 is installed in the fourth exhaust line 431, which is installed upstream of the second pump 250 in of the second exhaust path. The first and second exhaust control valves 521 and 523 are controlled to be alternately opened or closed depending on the type of the non-reacted reactant present in the material exhausted in the ALD process.

For instance, during a period in which the first reactant, for example, AX(g), is supplied from the first reactant supplier 151 to the reactor, only the first exhaust path is opened and the second exhaust path is closed. That is, the first exhaust control valve 521 is set to an open state, and the second exhaust control valve 523 is set to a closed state. Conversely, during a period in which the second reactant, for example, BY(g), is supplied from the second reactant supplier 155 to the reactor, only the second exhaust path is opened and the first exhaust path is closed. That is, the second exhaust control valve 521 is set to an open state, and the first exhaust control valve 523 is set to a closed state.

To periodically close or open the first and second exhaust control valves 521 and 523 in turn as described above, the first and second exhaust control valves 521 and 523 can be operated in conjunction with the corresponding first and second supply control valves 511 and 513. For example, operation of the first and second exhaust control valves 521 and 523 can be interlocked to the operation of the first and second supply control valves 511 and 513. That is, the first exhaust control valve 521 may be interlocked to open when the first supply control valve 511 is open, while the second exhaust control valve 523 may be interlocked to open when the second supply control valve 513 is open. The first and second exhaust control valves 521 and 523 may also be operated after an appropriate buffer time has elapsed from the opening of the first and second supply control valves 511 and 513. Also, although the valves may be mechanically coupled to provide interlocked operation, a valve driving controller 500 may be utilized to control the interlocking between and the activation sequence of the valves.

By suppressing the likelihood of a reaction between the non-reacted reactants and the resulting formation of solid by-products such as powders in the exhaust path, the exemplary embodiments provide an improved ALD apparatus requiring less repair and maintenance and increased uptime and throughput.

### Second Exemplary Embodiment

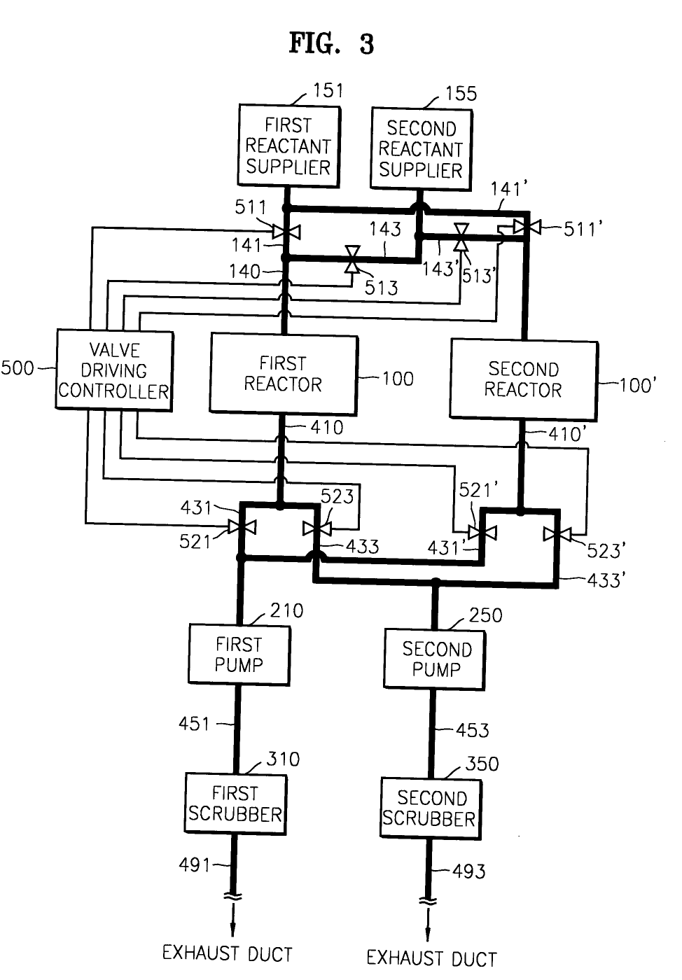

The second exemplary embodiment of the invention provides an ALD apparatus having a plurality of reactors that may be described with reference to FIG. 3. As shown in FIG. 3, the exhaust paths for the identical non-reacted reactants from the various reactors may be combined into a single exhaust path using a dedicated pump and a scrubber for each of the types of non-reacted reactants.

As illustrated in FIG. 3, when a plurality of reactors 100, 100′ provided in an ALD apparatus are used to perform ALD processes, the exhaust paths for exhausting the various non-reacted reactants may be used for the same non-reacted reactants from the various reactors. That is, the ALD apparatus may be configured so that exhaust paths and supply paths, such as reactant suppliers 151 and 155, pumps 210 and 250, and scrubbers 310 and 350, are commonly used to supply and exhaust the same reactants from each of the reactors.

Each of the reactors 100 and 100′ can be a single wafer type reactor, a mini-batch type reactor or a batch type reactor suitable for mass production for performing an ALD process on the wafer(s) loaded in the reactors. As described above, reactant suppliers 151 and 155 are coupled to the reactors 100 and 100′ through supply lines 140, 141, 141′, 143, and 143′, such that two or more types of reactants are sequentially and separately supplied to the reactors 100 and 100′ during the ALD process.

In a basic configuration, an exemplary apparatus includes reactant suppliers 151 and 155 for supplying two types of reactants, a first reactant supplier 151 for supplying a first reactant, for example, AX(g), and a second reactant supplier 155 for supplying a second reactant, for example, BY(g), may be coupled to the reactors 100 and 100′ through the supply lines. The apparatus may include, as illustrated in FIG. 3, supply lines 140, 141, 141′, 143, and 143′, as well as supply control valves 511, 511′, 513, and 513′ for opening or closing the supply lines.

As illustrated in FIG. 3, each of the reactant suppliers 151 and 155 may be coupled to the reactors 100 and 100′ to separately supply a reactant to the reactors. Thus, each of the reactants can be separately supplied to the reactors 100 and 100′. For example, the first supply line 141 connecting the first reactant supplier 151 and a first reactor 100, the third supply line 141′ connecting the first reactant supplier 151 and the second reactor 100′, the second supply line 143 connecting the second reactant supplier 155 and the first reactor 100, and the fourth supply line 143′ connecting the second reactant supplier 155 and the second reactor 100′ may be independently installed.

As shown in FIG. 3, supply control valves 511, 511′, 513, and 513′ may be installed in the supply lines 141, 141′, 143, and 143′. For example, the first supply control valve 511 is installed in the first supply line 141, the third supply control valve 511′ is installed in the third supply line 141′, the second supply control valve 513 is installed in the second supply line 143, and the fourth supply control valve 513′ is installed in the fourth supply line 143′. These supply control valves 511, 511′, 513, and 513′ control the supply or flow of each of the reactants during the ALD process to introduce the reactants separately and sequentially to the reactors 100 and/or 100′. The supply control valves 511 and 511′, and/or 513 and 513′, for supplying the identical reactants may also be interlocked to synchronize their operation.

The supply lines 141 and 143, and/or 141′ and 143′, may be independently coupled to the reactors 100 and 100′. Alternatively, as illustrated in FIG. 3, the supply lines 141 and 143, 141′ and 143′ may be combined into a corresponding inlet line 140 or 140′ that is, in turn, coupled to the reactor 100 or 100′. When the inlet lines 140 and 140′ are used, as illustrated in FIG. 3, the supply control valves 511, 511′, 513, and 513′ may be used to control the supply of each of the reactants to the reactors 100 and 100′ via the inlet lines. When the first or third supply control valves 511 or 511′ are opened to supply the first reactant, the corresponding second or fourth supply control valves 513 or 513′ are closed. Similarly, when the second or fourth supply control valves 513 are opened to supply the second reactant, the corresponding first or third supply control valves 511 or 511′ are closed

As described in the first exemplary embodiment of the invention, the number of the exhaust paths will typically be equal to the number of types of reactants that will be supplied to the reactors 100 and 100′. This configuration allows a different exhaust path to be used for exhausting each type of the non-reacted reactant which may be included in the material exhausted from the reactors 100 and 100′. For example, when the ALD process utilizes two types of reactants, two independent exhaust paths are preferably provided for removing reactant material from the reactors 100 and 100′. As illustrated in FIG. 3, a scrubber 310, 350 is preferably installed downstream from each pump 210, 250, provided in an exhaust path.

For example, a first exhaust path for exhausting the non-reacted first reactant from the first reactor 100 may include a first exhaust line 431, a first pump 210, a second exhaust line 451, a first scrubber 310, and a third exhaust line 491. A second exhaust path for exhausting the non-reacted second reactant from the first reactor 100 may include a fourth exhaust line 433, a second pump 250, a fifth exhaust line 453, a second scrubber 350, and a sixth exhaust line 493. A third exhaust path for exhausting the non-reacted first reactant from the second reactor 100′ may include a seventh exhaust line 431′, a first pump 210, a second exhaust line 451, a first scrubber 310, and a third exhaust line 491. A fourth exhaust path for exhausting the non-reacted second reactant from the second reactor 100′ may include an eighth exhaust line 433′, a second pump 250, a fifth exhaust line 453, a second scrubber 350, and a sixth exhaust line 493.

As illustrated in FIG. 3, the first exhaust line 431 and the fourth exhaust line 433 may branch from an outlet line 410 coupled to the reactor 100, and the seventh exhaust line 431′ and the eighth exhaust line 433′ may branch from a second outlet line 410′ coupled to the second reactor 100′.

In the second exemplary embodiment of the invention, the non-reacted first reactant is typically exhausted through the first exhaust path with the non-reacted second reactant being exhausted through the second exhaust path. To achieve this result, when the material exhausted from the first reactor 100 includes the non-reacted first reactant, the first exhaust path is opened and the second exhaust path is closed. Conversely, when the material exhausted from the first reactor 100 includes the non-reacted second reactant, the second exhaust path is opened and the first exhaust path is closed. Similarly, when the material exhausted from the second reactor 100′ includes the non-reacted first reactant, the third exhaust path is opened and the fourth exhaust path is closed and when the material exhausted from the second reactor 100′ includes the non-reacted second reactant, the fourth exhaust path is opened and the third exhaust path is closed.

Therefore, exhaust control valves 521 and 523 are installed to open or close the first and second exhaust paths, such that the first and second exhaust paths are selectively operated repeatedly and alternately in coordination with the ALD process. Also, exhaust control valves 521′ and 523′ are installed to open or close the third and fourth exhaust paths in an alternating manner, such that the third and fourth exhaust paths are selectively operated repeatedly in coordination with the ALD process.

For instance, the first exhaust control valve 521 is installed in the first exhaust line 431, which is upstream of the first pump 210 in the first exhaust path, and the second exhaust control valve 523 is installed in the fourth exhaust line 431, which is upstream of the second pump 250 in the second exhaust path. Similarly, the third exhaust control valve 521′ is installed in the seventh exhaust line 431′, which is upstream of the first pump 210 in the third exhaust path, and the fourth exhaust control valve 523′ is installed in the eighth exhaust line 431′, which is upstream of the second pump 250 in the fourth exhaust path. The first and second exhaust control valves 521 and 523 (or the third and fourth exhaust control valves 521′ and 523′) are controlled to be alternately opened or closed depending on the type of the non-reacted reactant present in the material exhausted being exhausted from the reactors during the ALD process.

For instance, during a period in which a first reactant, for example, AX(g), is supplied from the first reactant supplier 151 to the reactor, only the first exhaust path is opened and the second exhaust path remains closed. That is, the first exhaust control valve 521 is opened and the second exhaust control valve 523 is closed. Conversely, during a period in which a second reactant, for example, BY(g), is supplied from the second reactant supplier 155 to the reactor, only the second exhaust path is opened and the first exhaust path remains closed. That is, the second exhaust control valve 521 is opened, and the first exhaust control valve 523 is closed. The third and fourth exhaust control valves 521′ and 523′ may be operated in a similar manner.

The closing or opening of the first and second exhaust control valves 521 and 523 is typically coordinated with the operation of the first and second supply control valves 511 and 513. Similarly, the closing or opening of the third and fourth exhaust control valves 521′ and 523′ is typically coordinated with the operation of each of the first and second supply control valves 511′ and 513′.

For example, each of the first and second exhaust control valves 521 and 523 can be interlocked to operate in conjunction with the operation of the respective first and second supply control valves 511 and 513. That is, the first exhaust control valve 521 may be interlocked to open and close with the first supply control valve 511, while the second exhaust control valve 523 may be interlocked to open and close with the second supply control valve 513. It is also possible to delay operation of the first and second exhaust control valves 521 and 523 an appropriate buffer time after operation of the corresponding first and second supply control valves 511 and 513. Also, although the valves may be mechanically coupled to provide this interlocked function, a valve driving controller 500 may be utilized to control the synchronized operation of the various valves. Similarly, the third and fourth exhaust control valves 521′ and 523′ may be controlled by a valve driving controller 500 to coordinate their operation with the operation of the third and fourth supply control valves 511′ and 513′.

Here, although the exhaust paths are structured to support two or more reactors 100 and 100′, the pumps 210 and 250 and the scrubbers 310 and 350 can be configured with combined exhaust paths for dedicated use with the same reactants from a larger number of different reactors or reactor chambers. Accordingly, even if reactors in addition to reactors 100 and 100′ are installed in the ALD apparatus, the number of pumps and the number of scrubbers are still preferably matched to the number of types of reactants used in the ALD process.

As described above, when the non-reacted reactants used in the ALD process are separately exhausted from the reactors, mixing of the various non-reacted reactants can suppressed in the exhaust path. As a result, the formation of solid by-products such as powders, which may be generated by the reaction between the non-reacted reactants is also suppressed in the exhaust path. By suppressing the generation of the powders, the time and cost required for maintaining the exhaust path of an ALD reactor can be reduced.

While the present invention has been particularly shown and described with reference to preferred embodiments thereof, it will be understood by those of ordinary skill in the art that various changes in form and details may be made therein without departing from the spirit and scope of the present invention as defined by the following claims.

What is claimed is:

1. An atomic layer deposition apparatus, comprising:
a reactor;
a plurality of reactant suppliers arranged and configured to supply a plurality of N types of reactant to the reactor;
a plurality of N supply control valves arranged and configured to control the supply of the N types of reactant to the reactor; and
a plurality of N exhaust paths arranged and configured for the removal of the N types of reactant from the reactor;
wherein each of the N types of reactant is removed through a different one of the N exhaust paths.

2. An atomic layer deposition apparatus according to claim 1, further comprising:
a plurality of exhaust control valves arranged and configured to be selectively opened or closed to define each of the N exhaust paths.

3. An atomic layer deposition apparatus according to claim 1, wherein:
each of the N exhaust paths includes
a pump for drawing one of the N types of reactant from the reactor into a pump inlet and issuing an exhaust stream from a pump outlet;
a scrubber for treating the exhaust stream;
an exhaust line connecting the reactor to the pump inlet; and
an exhaust line connecting the pump outlet to the scrubber.

4. An atomic layer deposition apparatus according to claim 3, further comprising:
an exhaust control valve arranged in the exhaust line between the reactor and the pump inlet.

5. An atomic layer deposition apparatus according to claim 4, wherein:
a plurality of the N exhaust paths share a common portion of exhaust line.

6. An atomic layer deposition apparatus according to claim 5, wherein:
the common portion of exhaust line is arranged between the reactor and the exhaust control valves arranged in the plurality of the N exhaust paths.

7. An atomic layer deposition apparatus according to claim 4, further comprising:
a valve controller arranged and configured for the synchronized opening and closing of the supply control valves and exhaust control valves to define the N exhaust paths whereby each of the N types of reactant is removed from the reactor through a different one of the N exhaust paths.

8. An atomic layer deposition apparatus according to claim 7, further comprising:
an inert gas supply arranged and configured to supply an inert gas to the reactor.

9. An atomic layer deposition apparatus according to claim 7, wherein:
the reactor includes a plurality of deposition chambers.

10. An atomic layer deposition apparatus according to claim 9, wherein:
the valve controller is arranged and configured for the synchronized opening and closing of the supply control valves and exhaust control valves to define the N exhaust paths whereby each one of the N types of reactant is removed from the plurality of deposition chambers through one of the N exhaust paths.

11. A method of performing an atomic layer deposition comprising:
arranging a substrate in a reactor chamber;
supplying a first reactant to the reactor chamber;
absorbing a portion of the first reactant on the substrate to form a first reactant layer;
removing a remaining portion of the first reactant from the reactor chamber through a first exhaust path;
supplying a second reactant to the reactor chamber;
reacting a portion of the second reactant with the first reactant layer to form a material layer on the substrate; and
removing a remaining portion of the second reactant from the reactor chamber through a second exhaust path;
wherein the first exhaust path and the second exhaust path are arranged and configured to suppress the mixing of an exhausted portion of the first reactant with an exhausted portion of the second reactant.

12. A method of performing an atomic layer deposition according to claim 11, wherein:
supplying the first reactant to the reactor chamber includes opening a first supply control valve between a first reactant source and the reactor chamber;
removing the remaining portion of the first reactant from the reactor chamber through a first exhaust path includes opening a first exhaust control valve and drawing the remaining portion of the first reactant from the reactor chamber into a first pump;
supplying a second reactant to the reactor chamber includes opening a second supply control valve between a second reactant source and the reactor chamber;
removing the remaining portion of the second reactant from the reactor chamber through a second exhaust path includes opening a second exhaust control valve and drawing the remaining portion of the second reactant from the reactor chamber into a second pump;
wherein the opening and closing of the first exhaust control valve is synchronized with the opening and closing of the first supply control valve and
the opening and closing of the second exhaust control valve is synchronized with the opening and closing of the second supply control valve.

13. A method of performing an atomic layer deposition according to claim 12, wherein:
the operation of the first exhaust control valve and the operation of the second exhaust control valve are interlocked so that only one exhaust control valve is open at any given time during the atomic layer deposition.

14. A method of performing an atomic layer deposition according to claim 13, wherein:
the operation of the first supply control valve and the operation of the second supply control valve are interlocked so that only one supply control valve is open at any given time during the atomic layer deposition.

15. A method of performing an atomic layer deposition according to claim 12, wherein:
the operation of the first supply control valve and the operation of the first exhaust control valve are interlocked so that the first exhaust control valve opens a predetermined time after the first supply control valve is opened.

16. A method of performing an atomic layer deposition according to claim 15, wherein:
the operation of the first supply control valve and the operation of the first exhaust control valve are interlocked so that the first exhaust control valve closes a predetermined time after the first supply control valve is closed.

17. A method of performing an atomic layer deposition according to claim 12, wherein:
the operation of the second supply control valve and the operation of the second exhaust control valve are interlocked so that the second exhaust control valve opens a predetermined time after the second supply control valve is opened.

18. A method of performing an atomic layer deposition according to claim 17, wherein:
the operation of the second supply control valve and the operation of the second exhaust control valve are interlocked so that the second exhaust control valve closes a predetermined time after the second supply control valve is closed.

19. A method of performing an atomic layer deposition according to claim 12; wherein
the operation of the supply control valves and the exhaust control valves are controlled by a valve controller.

20. A method of performing an atomic layer deposition using N types of reactants in an apparatus according to claim 3, comprising:
arranging a substrate within the reactor;
opening a first supply control valve arranged between a first one of the N types of reactant suppliers and the reactor to allow a first reactant to enter the reactor;
absorbing a portion of the first reactant onto the substrate to form a first reactant layer;
closing the first supply control valve to terminate entry of the first reactant into the reactor;
opening a first exhaust control valves, thereby connecting the reactor to a first exhaust path, and removing substantially all of an unabsorbed portion of the first reactant from the reactor through a first pump provided in the first exhaust path to form a first exhaust stream;
closing the first exhaust control valve to disconnect the reactor from the first exhaust path;
after closing the first exhaust control valve and closing the first supply control valve, opening a second supply control valve arranged between a second one of the N types of reactant suppliers and the reactor to allow a second reactant to enter the reactor;
reacting a portion of the second reactant with the first reactant layer to form a material layer on the substrate;
closing the second supply control valve to terminate entry of the second reactant into the reactor;
opening a second exhaust control valve, thereby connecting the reactor to a second exhaust path, and removing substantially all of an unreacted portion of the second reactant from the reactor through a second pump arranged in the second exhaust path to form a second exhaust stream; and
closing the second exhaust control valve to disconnect the reactor from the second exhaust path; wherein
the first exhaust path and second exhaust path are arranged and configured to suppress mixing of the unabsorbed portion of the first reactant and the unreacted portion of the second reactant after their removal from the reactor.

21. A method of performing an atomic layer deposition using N types of reactants according to claim 20, further comprising:
passing the first exhaust stream through a first scrubber provided in the first exhaust path and to a common exhaust duct and
passing the second exhaust stream through a second scrubber provided in the second exhaust stream and to the common exhaust duct.
